(19) United States
(12) Patent Application Publication
(10) Pub. No.: US 2026/0321191 A1
(43) Pub. Date: Oct. 15, 2026

(54) DISPLAY DEVICE, DISPLAY SYSTEM, MULTIFUNCTIONAL ELEMENT AND METHOD FOR PRODUCING A DISPLAY DEVICE

(71) Applicant: FRAUNHOFER-GESELLSCHAFT ZUR FOERDERUNG DER ANGEWANDTEN FORSCHUNG E.V., Muenchen (DE)

(72) Inventors: Michael Jank, Erlangen (DE); Daniel Joch, Erlangen (DE); Thomas Lang, Erlangen (DE)

(21) Appl. No.: 19/205,880

(22) Filed: May 12, 2025

(30) Foreign Application Priority Data
May 13, 2024 (DE) 10 2024 204 420.2

(51) Int. Cl. G09G 3/32; H01H 13/02

(52) U.S. Cl. CPC G09G 3/32; H01H 13/023; G09G 2300/0426; G09G 2300/0452

(57) ABSTRACT

A display device has a plurality of display elements and an interconnection device configured to interconnect different and disjoint subsets of the display elements with one another. Display elements of a subset can be driven together by means of the interconnection device.

### CROSS-REFERENCE TO RELATED APPLICATION

This application claims priority from German Application No. 10 2024 204 420.2, which was filed on May 13, 2024, and is incorporated herein by reference in its entirety.

### TECHNICAL FIELD

The present invention relates to a display device, to a display system having such a display device, to a multifunctional element having a display system and to a method for producing a display device. The present invention relates in particular to representing simple symbols.

### BACKGROUND OF THE INVENTION

With regard to display technology for high-resolution displays, there are advantageously solutions with individual driving of the luminous areas (pixels). This includes passive matrix displays in which a desired voltage is applied directly between the anode and cathode of a luminous or brightness-regulating element (light-emitting diode/LED, organic light-emitting diode/OLED, liquid crystal/LC) in order to enable the emission or transmission of light (cf. [1], FIG. 13 in connection with FIGS. 12 and 8). In this case, as can be seen in [1], FIG. 13, only one line is actively luminous, the overall image is obtained by rapid switching between the lines benefitting from the inertia of the human eye or of the active element (e.g. afterglow LED, reset LC). In order to achieve a complete illustration without flickering in the case of large display elements, the applied pixel voltages and thus the brightness of the luminous element are maintained via an auxiliary circuit including driver element (transistor) and storage capacitor until the line is written again. The corresponding interconnection is referred to as active matrix circuit (cf. [1], FIGS. 14 and 16).

Both matrix driver variations have a connection line for each line and each column; in the case of n×k luminous elements, this results in n+k drive lines which are supplied in a time-synchronized manner by corresponding driver circuits (ICs). ([1], FIG. 11). Static or moving images (videos) can be displayed as desired with these displays in accordance with the resolution. Further IC modules are necessary for conditioning from common sources and providing the energy supply ([1], FIG. 20 and [2], FIG. 1).

If a freely definable output can be dispensed with in the case of simple information reproduction and reduced demands on variability and flexibility, directly driven (direct drive) luminous elements are a suitable solution. For this purpose, one or more luminous areas are driven which either represent the image element (symbol) itself ([1], FIG. 5) or one/more parts of the symbol ([1], FIG. 4). The latter element is widely used as a 7-segment display, e.g. for time display (for example in the case of a microwave, a digital LCD alarm, etc.), and uses the selection of different symbol combinations to display different symbols (at least 0-9, additionally letters, etc.) with a reduced set of luminous areas (7). A common characteristic of direct-drive displays is that each luminous area has exactly one control line in addition to the ground line ([1], FIG. 4). However, a luminous element can only be activated or deactivated in its entirety, so that symbols, as shown in [1], FIG. 5, generally have to be placed next to one another.

A further possibility for illustrating symbols with optional driving or coloring is represented by templates which are installed, for example, in tachometer displays or pushbuttons. Here, a template serves to define the luminous area. Background lighting on/off or color 1/color 2/off allows a context-dependent reproduction of information, see FIG. 8, which is set up to represent one or more symbols 1002₁ to 1002₆. In other words, FIG. 8 shows a backlit template in an operating unit according to [3].

While the high-resolution displays mentioned before are complex devices, display devices according to FIG. 8 offer comparatively small representation possibilities, but use a large amount of space.

Accordingly, a display device, a display system, a multifunctional element with a display system and a method for providing a display device would be desirable, which make it possible to represent a comparatively large amount of symbols with little space expenditure and at the same time to keep the degree of complexity of the device low.

An object of the present invention is therefore to provide a display device, a display system, a multifunctional element with a display system and a method for providing a display device, which make it possible to display several symbols with little space expenditure and at the same time a low degree of complexity.

### SUMMARY

According to an embodiment, a display device may have: a plurality of display elements; an interconnection device configured to interconnect different and disjoint subsets of the display elements with one another; wherein display elements of a subset can be driven together by means of the interconnection device.

According to another embodiment, a display system may have: a display device as mentioned above; and a control device configured to select at least one of the subsets of the display elements as a selected subset for driving and to drive the at least one selected subset together by means of the interconnection device.

According to another embodiment, a multifunctional element for a system may have: a display system as mentioned above, wherein the multifunctional element is configured to drive a subset of display elements associated to the operating state depending on an operating state of the system so that the display device represents a pattern associated to the operating state.

According to another embodiment, a method for producing a display device may have the steps of: arranging a plurality of display elements; and interconnecting the plurality of display elements into different and disjoint subsets; so that display elements of a subset can be driven together by means of the interconnection device.

According to another embodiment, a method for producing a display device may have the steps of: defining image contents of a display device; and implementing the image contents in a technology of the display device.

A core idea of the present invention is having recognized that it may be sufficient for the perception of a symbol to use only predefined subsets, such as subpixels of a pixel, in a matrix display and to perform grouping of display elements into disjoint subsets so that individual symbols can be driven (or activated) with the disjoint subsets, which is easily possible. At the same time, an interleaving of the display elements can be performed based on such a grouping, should this be necessary, so that a large amount of symbols can be represented in a space-saving manner and this is accompanied by little complexity expenditure.

According to an embodiment, a display device comprises a plurality of display elements and an interconnection device configured to interconnect different and disjoint subsets of the display elements with one another. Display elements of a subset can be driven together by means of the interconnection device.

According to an embodiment, a display system comprises such a display device and a control device configured to select at least one of the subsets of the display elements as a selected subset for driving and to drive the at least one selected subset together by means of the interconnection device.

According to a further embodiment, a multifunctional element comprises such a display system and is configured to drive a subset of display elements associated to the operating state depending on an operating state of the system in which the multifunctional element is used, so that the display device represents a pattern associated to the operating state.

According to an embodiment, a method for producing a display device comprises arranging a plurality of display elements and interconnecting the plurality of display elements into different and disjoint subsets so that display elements of a subset can be driven together by means of the interconnection device.

### BRIEF DESCRIPTION OF THE DRAWINGS

Particularly advantageous embodiments of the present invention will be explained below referring to the appended drawings, in which:

FIG. 1a shows a schematic top view of a display device according to an embodiment;

FIGS. 1b-c show a schematic top view and side sectional view of an interconnection of display elements according to an embodiment;

FIG. 2a shows a schematic top view of a display device according to an embodiment, which comprises several pixels which may be arranged in a regular arrangement of four rows and four columns;

FIG. 2B shows a schematic enlarged top view of a pixel of the display device of FIG. 2a;

FIG. 3a shows a schematic block diagram of the pixel according to FIG. 2b, wherein each display element according to an embodiment has a light-emitting element;

FIG. 3b shows a schematic block diagram of a pixel, which is varied compared to FIG. 3a, according to an embodiment, in which nine display elements in a 3×3 arrangement as respective subpixels form the pixel;

FIGS. 4a-d show schematic representations of a display device according to an embodiment and a grouping of display elements into different subsets for representing predefined patterns;

FIG. 4e show schematic representations of an interconnection of subpixels of a pixel;

FIGS. 5a-d show schematic block diagrams of a display system, which comprises a display device described herein and a control device, according to an embodiment;

FIG. 6a shows a schematic block diagram of a multifunctional element according to an embodiment in a first operating state;

FIG. 6b shows a schematic block diagram of the multifunctional element of FIG. 6a in another operating state;

FIG. 7a shows a schematic flow chart of a method according to an embodiment;

FIG. 7b shows a schematic flow chart of a further method according to an embodiment; and

FIG. 8 shows a picture of a known backlit template in an operating unit.

### DETAILED DESCRIPTION OF THE INVENTION

Before embodiments of the present invention will be explained in detail below referring to the drawings, it is pointed out that identical, functionally identical or identically acting elements, objects and/or structures in the different figures are provided with the same reference numerals so that the description of these elements illustrated in different embodiments is interchangeable or mutually applicable.

Embodiments described below will be described in connection with a plurality of details. However, embodiments can also be implemented without these detailed features. Furthermore, for the sake of comprehensibility, embodiments will be described using block diagrams as a replacement of a detailed representation. Furthermore, details and/or features of individual embodiments can be easily combined with one another as long as not the contrary is explicitly described.

The following embodiments will be described referring to terminology, such as, for example, pixels and subpixels. In this case, a pixel or image element can comprise several subpixels, which is used, for example, in matrix-based displays. Starting from a matrix-based display configuration, embodiments can relate to associating different subpixels to different patterns or to using different subpixels of a pixel for different patterns or to not using one or more of the subpixels or to configuring them to be dysfunctional at least for the display, which does not rule out an arrangement of a sensor device at this point. The terms pixel and subpixel are in this case selected merely for the sake of better clarity of the embodiments and can be used starting from known production processes of matrix-based displays. However, this is not intended to restrict the subject-matter of the present invention to such a configuration.

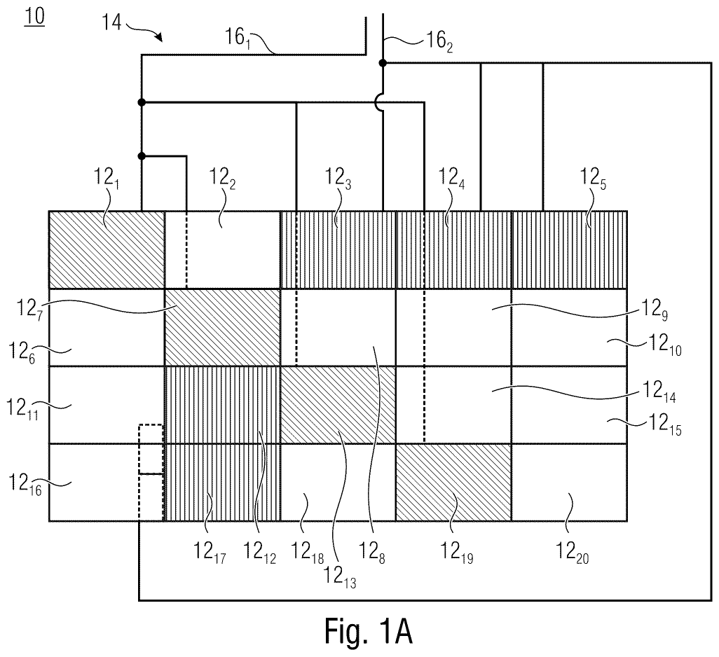

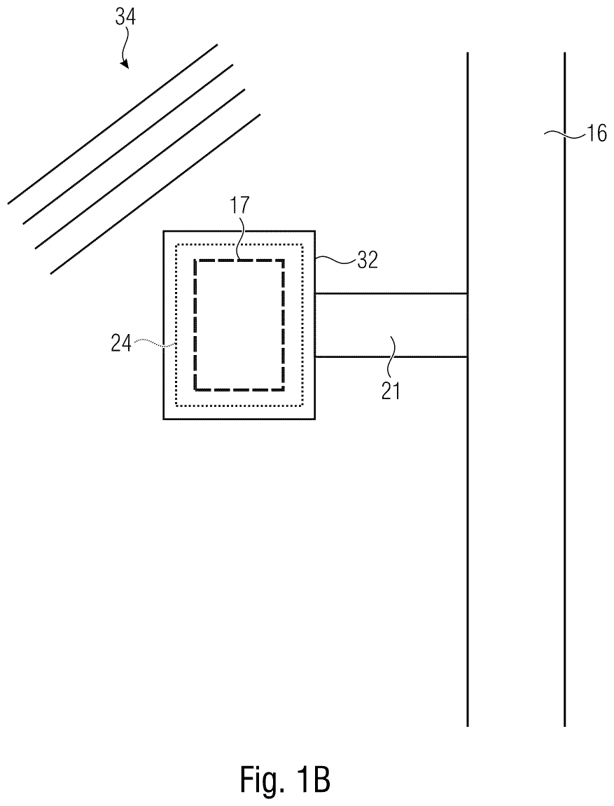

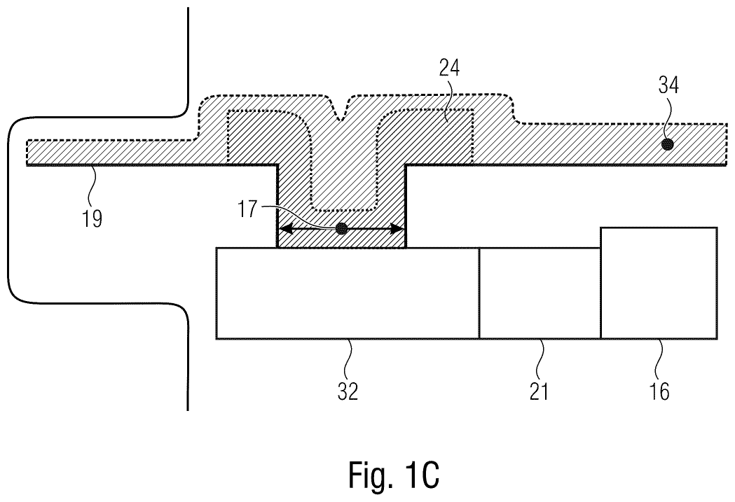

FIG. 1a shows a schematic top view of a display device 10 according to an embodiment. The display device 10 comprises a plurality of display elements 12₁ to 12₂₀.

According to an embodiment, the plurality of display elements 12₁ to 12₂₀ are arranged in a regular array with a plurality of columns and a plurality of rows. The display elements 12₁ to 12₂₀ can thus be positioned in a matrix-like arrangement, wherein this is not necessary. In this respect, an arrangement in the form of rows and columns can be implemented, but also any other form of arrangement. Furthermore, the plurality of display elements 12₁ to 12₂₀ can have corresponding display elements with respect to a surface area or a group-specific display surface geometry and/or surface areas. In other words, each of the display elements 12₁ to 12₂₀ can be configured, with respect to a shape, a geometry, a surface area, but also with respect to other properties, such as a color with which information are displayed or light is output, and/or a brightness, identically individually or globally in groups or display elements.

The display device 10 further comprises an interconnection device 14 configured to interconnect different and disjoint subsets of the display elements with one another. Thus, for example, display elements 12₁, 12₇, 12₁₃ and 12₁₉ can form a first group of display elements which can be driven together, for example, via a signal on a driving line 16₁. In other words, in the present representation, the display elements 12₁, 12₇, 12₁₃ and 12₁₉ are wired fixedly to one another and are driven together, that is to say they are active or inactive together.

A subset of display elements 12₃, 12₄, 12₅, 12₁₂ and 12₁₇ disjoint therefrom can be driven with a further driving line 16₂ of the interconnection device 14, that is to say the display elements 12₃, 12₄, 12₅, 12₁₂ and 12₁₇ are wired fixedly to one another and are activated or deactivated together.

The interconnection into disjoint subsets results in a display element 12₁ to 12₂₀ being associated to at most one subset or being drivable via at most one driving line 16.

It is possible, but not necessary, for each display element 12₁ to 12₂₀ to be associated to a subset.

According to an embodiment, the interconnection device 14 is configured to interconnect the subsets of the display elements invariably with one another, which can also be referred to as fixed wiring.

According to an embodiment, each of the subsets 12₁, 12₇, 12₁₃ and 1219, on the one hand, and 12₃, 12₄, 12₅, 12₁₂ and 12₁₇, on the other hand, can be driven unambiguously via a driving line 16₁ or 16₂ unambiguously associated to the subgroup.

At this point, it is to be pointed out that the position and/or number of the display elements of a subgroup as well as the number of subgroups as well as the number of display elements in the display device 10 can be configured as desired. Thus, the number of display elements is advantageously at least three, at least five, at least ten, greater than 100, greater than 1000 or even greater. The number of display elements per subgroup is at least two, but is advantageously greater, for instance at least ten, at least 20 or at least 100. The number of subgroups can correspond to the number of two, but can advantageously also be configured to be greater, for example at least three, at least five, at least ten or at least 20.

In an advantageous implementation, each of the subsets is unambiguously associated to a predefined pattern to be represented by the display device 10 or each of the subsets is unambiguously associated to a predefined pattern to be represented by the display device. The display device 10 can be configured to represent the predefined pattern associated to the subset by means of the common driving of the display elements. This means that a pattern to be represented can be represented via addressing the driving line 16₁ or 16₂ associated to the subset of display elements 12₁ to 12₂₀. However, it is possible, in particular when using a higher number of subsets and a higher number of driving lines 16, to output a combinatorial pattern by driving several of the driving lines 16 by the display device 10.

In connection with some of the embodiments described herein, reference is made to subpixels, which form parts of a pixel, wherein subpixels of different pixels can be interconnected to form a subset of subpixels, which can in turn be jointly driven based on the interconnection. The term interconnection for driving a subpixel can be understood in such a way that essentially a connection of the subpixel takes place by means of a conductor track. FIG. 1b and FIG. 1c show a schematic top view and a schematic side sectional view of an implementation of the interconnection which is possible but not necessary within the framework of the embodiments.

A light-emitting element or luminous element 24 can be arranged between a first electrode 32, like an anode, and a second electrode 34, like a cathode. The light-emitting element 24 can be contacted electrically with the electrode 32 in the region of an opening or recess 17 of an insulator 19. A subpixel connection 21 can produce, as an electrical line, an electrical connection with a common driving line 16 for the group or subset, wherein the driving line 16 and the subpixel connection can consist of the same material or different materials and/or of one or more structures or pieces.

There are a plurality of possibilities for performing driving of the subpixel or the group of display elements.

In a possible implementation, each subpixel is unambiguously allocated or associated to one of the disjoint subpixel groups which is selected via the control line 16. The decision as to whether a pixel is illuminated or not possibly takes place within the framework of advantageous implementations
via the interconnection or arrangement or execution or non-execution of the subpixel connection (21),
via replacement of the connection (21) by a programmable element, like a resistive element,
via execution or non-execution of the electrode 32 at the location of the subpixel, like to the effect that some regions are incapable of functioning with respect to light emission in the absence of the electrode,
via execution or non-execution of the opening 17 in the insulation layer, like in an implementation of the display device as an OLED display, like to the effect that some regions are incapable of functioning with respect to light emission in the absence of the opening;
via execution or non-execution of the luminous element 24, like in an implementation as a μLED display, like to the effect that some regions are incapable of functioning with respect to light emission in the absence of the luminous element; and/or
the application of an optically dense brightness filter above the subpixel, i.e., on a side of the luminous element 24 facing away from the electrode 32, on which side the observer is generally located, so that the element possibly illuminates but does not emit.

Each of these mechanisms can be understood or subsumed as interconnection within the framework of the embodiments so that the subpixel connection 21 is a possible but not necessary implementation.

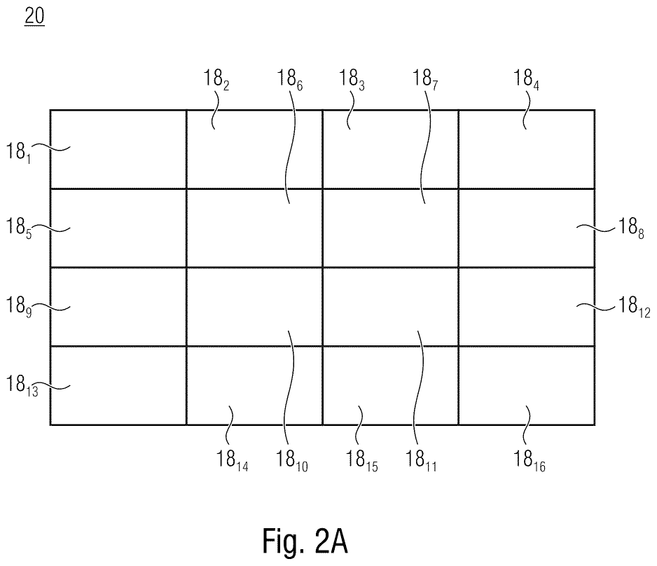

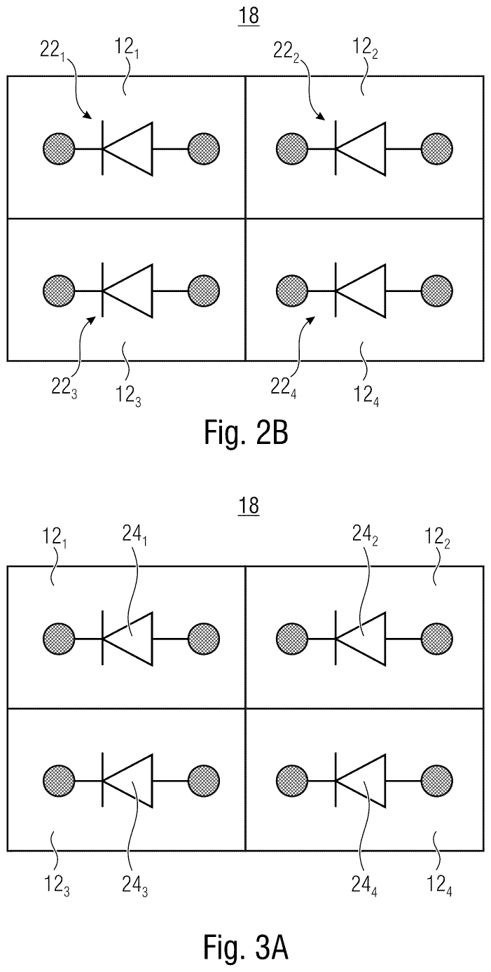

FIG. 2a shows a schematic top view of a display device 20 according to an embodiment. This comprises by way of example pixels 18₁ to 18₁₆, which may be arranged in a regular arrangement of four rows and four columns, wherein both the number of pixels and the number of columns and the number of rows are selected merely by way of example and may have different, in particular larger values.

FIG. 2b shows a schematic top view of a pixel 18 of the display device 20. The pixel 18 comprises four display elements 12₁ to 12₄, for example, which may be arranged in a 2×2 arrangement with two columns and two rows, wherein here, too, the number of columns, the number of rows and/or the number of display elements may be implemented differently, for example merely one row or alternatively merely one column or more than two rows and/or more than two columns. It is illustrated by means of diode symbols 22₁ to 22₄ that each of the display elements 12₁ to 12₄ can be driven individually and can output optical information or emit light in response to an electrical signal, for example, for which light-emitting diodes, LEDs, may be suitable, for example, but not exclusively. When viewing or assigning the display elements 12₁ to 12₄ as a pixel, the display elements 12₁ to 12₄ may be considered as subpixels of the pixel. For example, each of the subpixels 12₁-12₄ can comprise at least one light-emitting element, like a light-emitting diode, LED.

When viewed together with FIG. 2a, it becomes clear that the individual pixels 18₁ to 18₁₆ with an interconnection device 14 of the display device 10 can be used differently for different symbols and that the different symbols can be represented on a display or a display device in a simple manner by using only one driving line 16₁/16₂ for each symbol, optionally in combination with an individual or combined return line.

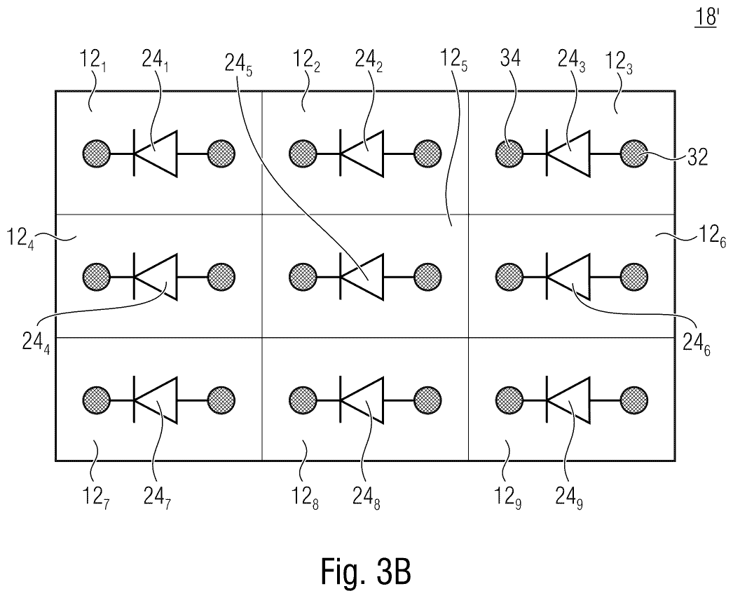

FIG. 3a shows a schematic block diagram of the pixel 18 according to FIG. 2b, wherein each display element or subpixel 12₁-12₄ comprises a light-emitting element 24₁-24₄. Additional light-emitting elements, connected in series or in parallel, for example, for representing a color mixture or for increasing the brightness, for example, are not excluded according to embodiments.

FIG. 3b shows a schematic block diagram of a pixel 18′, which is varied compared to FIG. 3a, in which nine display elements 12₁-12₉ in a 3×3 arrangement as respective subpixels form the pixel 18′. Another number of rows and/or another number of columns as well as an arrangement varying from a matrix arrangement are not excluded according to embodiments.

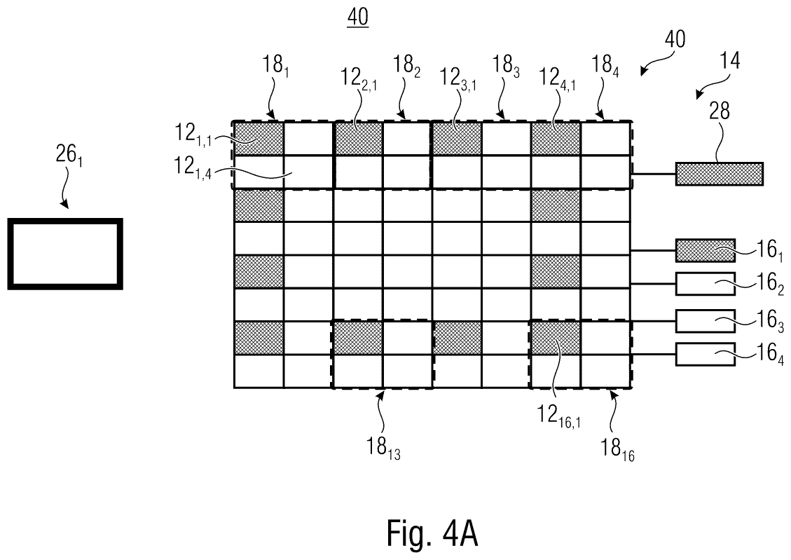

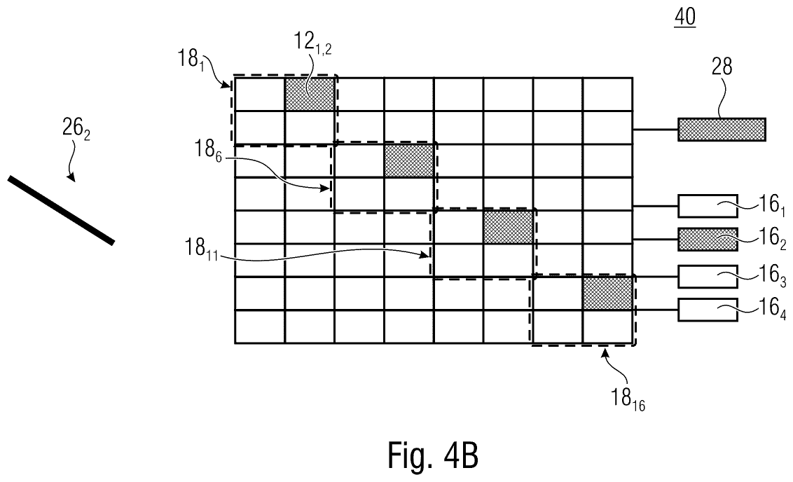

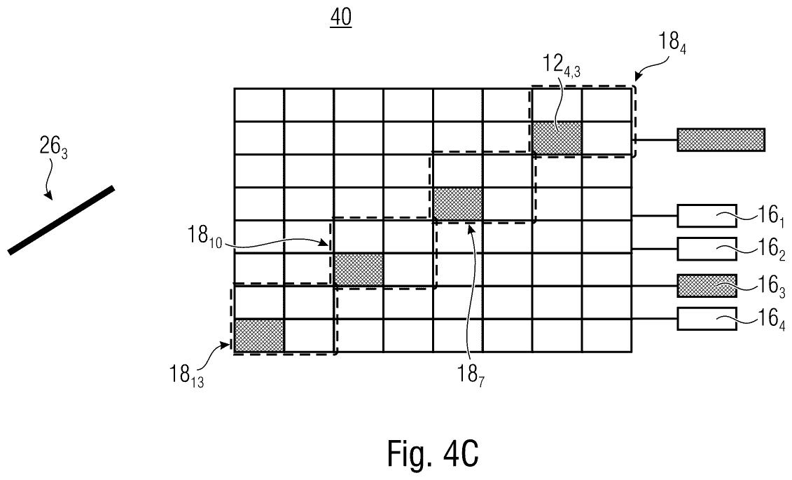

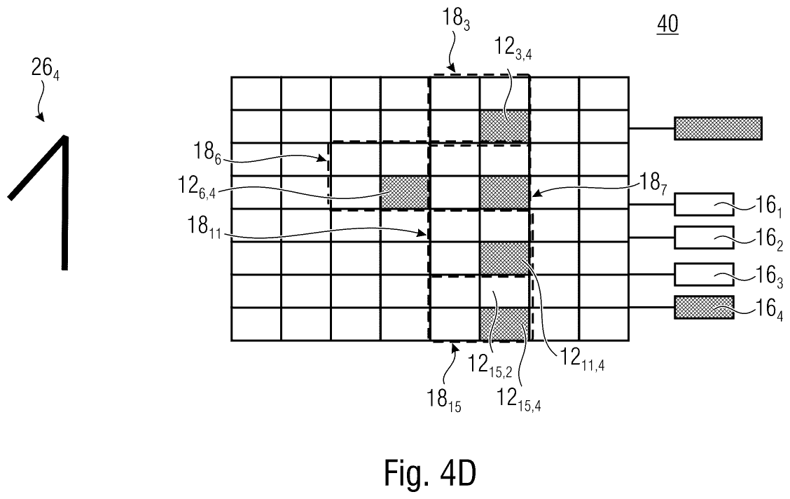

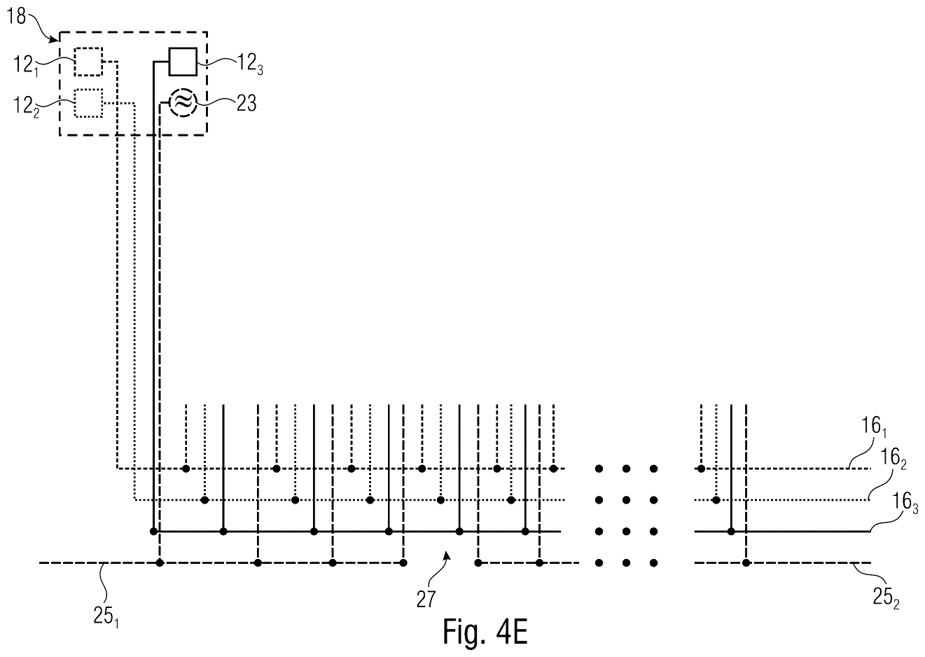

FIG. 4a shows a schematic representation of a display device 40 according to an embodiment, which comprises, for example, 16 pixels 18₁-18₁₆ with a respective configuration of the pixels according to FIGS. 2b and 3a. The number of pixels is in this case selected merely by way of example and may in particular be significantly larger. Each of the pixels 18₁-18₁₆ comprises display elements 12i, j, wherein the parameter i indicates the pixel of the display element and the parameter j describes a sequence number within the pixel 18.

The display device 40 can be configured to represent, by way of example and using the display elements 12_{i,j}, four patterns 26₁, 26₂, 26₃ and 26₄, wherein the patterns 26₁-26₄ are selected merely by way of example and not in a limiting manner, in order to further illustrate the advantages of the present invention.

For example, the display elements 12_{i,1} of the display device 40 can be interconnected with one another to form a first subset, which can be driven via a first driving line 16₁, in order to make a rectangular pattern or square pattern 26₁ perceptible to the observer, for example. A common return line 28 of the subsets, which can be driven by the driving lines 16₁, 16₂, 16₃ and 16₄, respectively, can be contacted for representing several or even all of the patterns 26₁-26₄.

While for the pattern 26₁, for example, all of the display elements 12_{i,1} can be contacted with the interconnection device 14 and can be driven by the driving line 16₁, for other patterns, for example the pattern 26₂, only one display element 12i,j of a subset of the pixels can be contacted. Thus, for example, the display elements 12i,2 of the pixels 18₁, 18₆, 18₁₁ and 18₁₆ can be interconnected to form a second subset, which can be driven, for example, via the driving line 16₂, in order to represent a diagonal line of the pattern 26₂.

FIG. 4c shows an interconnection of display elements 12_{i,3} of the pixels 18₄, 18₇, 18₁₀ and 18₁₃, which can be driven jointly via the driving line 16₃, in order to make a likewise diagonal line perceptible to an observer as a pattern 26₃. The pattern 26₃ is, for example, inclined with respect to the pattern 26₂, like by 90 degrees due to the arrangement of the display elements.

According to embodiments, a driving device can drive only one of the driving lines 16₁-16₄ or none of the driving lines 16₁-16₄ at a point in time. According to a further embodiment, a control device is configured to drive several of the driving lines 16₁-16₄ at a point in time. Thus, for example, an x-pattern could be representable to the observer by jointly driving the driving lines 16₂ and 16₃.

FIG. 4 shows an interconnection of a further, fourth subset of display elements, in which the display elements 12i,4 of the pixels 18₃, 18₆, 18₇, 18₁₁ and 18₁₅ are interconnected with one another, in order to represent the pattern 26₄, like a “1”, to the observer when driven via the joint driving line 16₄.

It is shown that pixels can each be a part of several representable patterns, like the pixel 18₃ for the patterns 26₁ and 26₄, the pixel 18₆ for the patterns 26₂ and 26₄ or the pixel 18₁₁ for the patterns 26₂ and 26₄. For the respective different patterns, different display elements 12 of a pixel 18 can be activated via driving with different driving lines 16₁-16₄.

The smaller the respective display element 26₁-26₄ is configured, the closer the observer can come to the display device and at the same time perceive the patterns 26₁-26₄ in good quality. Quality losses can be accepted, like in that information are nevertheless reproduced reliably. A luminous area of a display element can be selected as desired and in advantageous embodiments can, for example, have a size in a range of 50-100 μm². Thus, for example, a micro-LED (μLED) can be used as display element, which can have an edge length of the light-emitting area in a range of about 10 μm. More meaningful for a display, however, is the density of display points, which in embodiments can be at least 300 dpi (points/dots per inch), at least 400 dpi or at least 500 dpi.

An association of four display elements 12 to a pixel 18 in combination with a representation possibility of four patterns 26₁-26₄ with the display device 40 is in this case, however, selected merely by way of example and not in a limiting manner. The display device 40 could furthermore be configured to represent at least a fifth pattern, like a vertical line, for example, in the second column of the display device, since both the pixel 18₂ and the pixels 18₆, 18₁₀ and 18₁₃ comprise display elements, which are not yet associated to any of the patterns 26₁-26₄.

It is furthermore to be noted that a fixed association of a display element position within a pixel to a specific pattern can be exemplarily and also simple and thus advantageous for production, but it is also quite possible to deviate from such a configuration. Thus, for example, for the pattern 26₄, the display element 12_{15.2} could easily be used instead of the display element 12_{15.4}. Similarly, other display elements can be associated to patterns as desired, wherein it is of advantage for a display element to be associated to only one subset, which is driven in each case via a driving line 16₁-16₄, and for the subset of display elements to be disjoint to one another.

Further advantageous implementations will be explained referring to the display device 40. According to an embodiment, a display device is provided, in which a first color filter is arranged with respect to one, several or all display elements of a first subset of display elements. This can be used for coloring or color manipulation of at least one of the patterns 26₁-26₄. Optionally, a second color filter can be arranged with respect to display elements of a second subset of display elements. One or more of the color filters used can be controllable, for example with respect to the transmission wavelength, the transmittance and/or an operating state, for example on/off. Thus, for example, an implementation of the display device 40 may be such that one of the patterns 26₁-26₄ can be represented multiple times and each of the representations is combined with a different color filter.

According to an embodiment, a deviation from such a configuration is such that at least one color filter is provided, which is arranged with respect to at least one display element and opposite to a viewing direction of the display device, that is, between the light-emitting element and the observer. The color filter can be configured to filter light provided by the display element.

According to a further embodiment, the display device is configured such that the display elements of a subset have a common contacting, for example the driving lines 16₁, 16₂, 16₃ or 16₄. When the common contacting is wired, either none of the display elements of the subset is activated or all of the display elements of the subset are activated.

In this case, for example, the driving lines 16₁-16₄ can provide one of the forward line and the return line of the respective subset and the remaining element, for example the return line or alternatively the forward line, can be combined for different subsets or even all of the subsets, for example in the return line 28, since this still makes individual driving in groups possible.

According to an embodiment, a display device is provided, in which each display element has a first electrical connection and a second electrical connection. With reference to FIG. 3b, this can be an anode 32 of a diode/LED, for example. Correspondingly, a cathode 34 or a cathode connection can be arranged as the second connection. Other designations of electrical connections or electrical poles can be used for other elements. According to the embodiment, first connections of different display elements of a subset of the display elements can be interconnected with one another by means of the interconnection device 14 and electrically separated from first connections of display elements of other subsets. Second connections, for example the cathode connections 34 of display elements of different subsets, can be interconnected with one another by means of the interconnection device 14, for example contactable via the common return line 28 in FIGS. 4 a-d.

According to an embodiment, the plurality of display elements is a plurality of subpixels which is grouped into a smaller plurality of pixels. It is of advantage that each subpixel is allocated to at most one group/subset. Each subset of display elements advantageously comprises at most one subpixel of a pixel. This means that each subset of display elements comprises either no subpixel or exactly one subpixel in a pixel.

According to an embodiment, the display device is configured such that different subpixels of a pixel are driven when driving different subsets of the display elements, for example the display elements 12_{1,1} and 12_{1,2} when jointly driving the driving lines 16₁ and 16₂ for representing the patterns 26₁ and 26₂.

For a simple production of the display device, it can be of advantage for each pixel of the display device to have a matching number of subpixels. In the display device 40, these are, for example, four pixels and in the pixel 18′ of FIG. 3b, for example, nine. As has already been discussed, a deviation from such a number can be made and the number of rows and/or columns can be selected as desired.

According to an embodiment, the plurality of display elements of a display device is configured for providing a matching display brightness, a display brightness matching in groups or an individual display brightness. This can be selected, for example, depending on the pattern to be represented. Alternatively or additionally, a resistive element can be used, which is, for example, a part of the supply line or driving line 16₁-16₄ or is connected in series with it and is thus connected in the circuit of at least one of the subsets of display elements. Using the resistive element, a brightness of the display elements can be set, wherein the brightness can decrease, for example, with increasing ohmic resistance. According to a particularly advantageous embodiment, the resistive element is a controllable element, in particular a programmable resistive element. This can be driven, for example, by a control device in order to also set the brightness of the representation in addition to the represented pattern.

According to an embodiment, a display device comprises a brightness attenuation element, which is arranged, with respect to at least one of the display elements, opposite to a viewing direction and is configured to attenuate a brightness provided by the display element opposite to the viewing direction, that is, the brightness perceived by the observer. According to a particularly advantageous embodiment, the brightness attenuation element is controllable with respect to a degree of attenuation with which the brightness of the display element is attenuated, for example by a control device coupled to the display device.

A further advantageous implementation will be discussed referring to FIGS. 4a-d. A display device according to an embodiment can comprise at least one sensor element, advantageously a plurality of sensor elements, for example a photodetector element, wherein the sensor element is associated exactly to a subset of display elements. When using a plurality of sensor elements, each of the sensor elements can be associated exactly to a subset of display elements, wherein a subset of display elements can comprise no, one or several sensor elements. Sensor elements used can be of the same type or also different types. A type of sensor element can be, for example, a photodetector element. Alternatively or additionally, proximity-sensitive or touch-sensitive sensor elements can also be used, for example capacitive sensors, like touch sensors. These can be used for evaluation/reading, for example for gesture control. Such elements can be used in different ways. Thus, for example, a distinction can be made by an evaluation device or control device as to whether an object or a user is located in a specific area of the display, for example in front of the left half or the right half. Alternatively, camera functionalities or the like can also be implemented.

Alternatively or additionally, brightness control or brightness regulation can also be implemented, for example by providing additional possibly controllable brightness sources. These can be implemented, for example, comprising LCD pixels. Alternatively or additionally, an ambient brightness can be detected, for example for controlling the luminosity.

Although it is of advantage in the sense of the production process to configure pixels 18 identically and to vary them with respect to the interconnection or to associate them to different subsets, different pixels can also be different with respect to the display elements and/or the arrangement of sensor elements and/or the type of sensor elements.

FIG. 4e shows a schematic representation of an interconnection of pixels, wherein, for the sake of better clarity, only one pixel 18 is shown, which can have the display elements 12₁ to 12₃ or a different number, and furthermore a sensor element 23 is arranged in a plurality of or each pixel, which can be addressable via a control line 25 similar to the driving lines 16₁ to 16₃. In order to drive different subregions of the display device differently, at least one interruption 27 of the control line 25 can be provided in order to generate two or more segments 25₁ and 25₂, which can then be contacted individually. Since the sensor system can be accommodated, for example as shown, on every fourth subpixel of a pixel, i.e. within a disjoint group, this can initially have a clearly delimited connection, for example via the line 25. A spatial resolution can be achieved, for example, by different subpixel groups, for example those of the left image half and those of the right image half, being combined separately or of a corresponding finer resolution. Sensor elements 23 of different pixels can be interconnected into one of at least one or also several groups of sensor elements.

Referring to the display device 40, for example, locations of the display device where no display element is used for one of the patterns 26₁ to 26₄ can be replaced by a sensor element, for example a location of the display element 12_{1,4}. Such a sensor element can in this case also use a smaller size in the grid arrangement than would be available as installation space. According to an embodiment for using sensor elements, for example, one quadrant, two quadrants or three quadrants of a 2×2 arrangement of a pixel, as is shown, for example, in FIG. 3a, can be equipped with display elements and at least one quadrant with a sensor element. Other arrangements, for example an arrangement according to FIG. 3b or others make additional possibilities of implementation possible, as well as an arrangement of display elements in an arrangement deviating from a matrix arrangement.

According to an embodiment, as an alternative to using the installation space of an unused display element for a sensor element, the corresponding regions or surface regions of the display device 40 can also be rendered unusable in some other way, which provides a high insusceptibility to errors. According to such an embodiment, a display device is provided with at least one subregion of an arrangement, like a matrix arrangement, of the display elements, which is associated with a display element in the arrangement and is formed incapable of functioning with respect to a display function. This means that the plurality of display elements within a group which are not activated can be real, that is to say manufactured display elements which are not connected or contacted by a driving line. Alternatively, it is possible for such display elements to be connected, but to be processed as incapable of functioning by design, like by deliberately omitting an opening through an insulation layer or the like. This can lead to the fact that there are pixels/subpixels or areas on the display, in which no physical subpixel can be found due to the design at specific positions associated with individual subpixels within the pixel. Depending on the manufacturing process, it can be easier to implement the light-emitting region to be incapable of functioning or to redesign the wiring, that is the driving lines, accordingly. In both cases, a subpixel incapable of functioning on the one hand and the absence of contacting on the other hand, the emission of light at this location can be avoided.

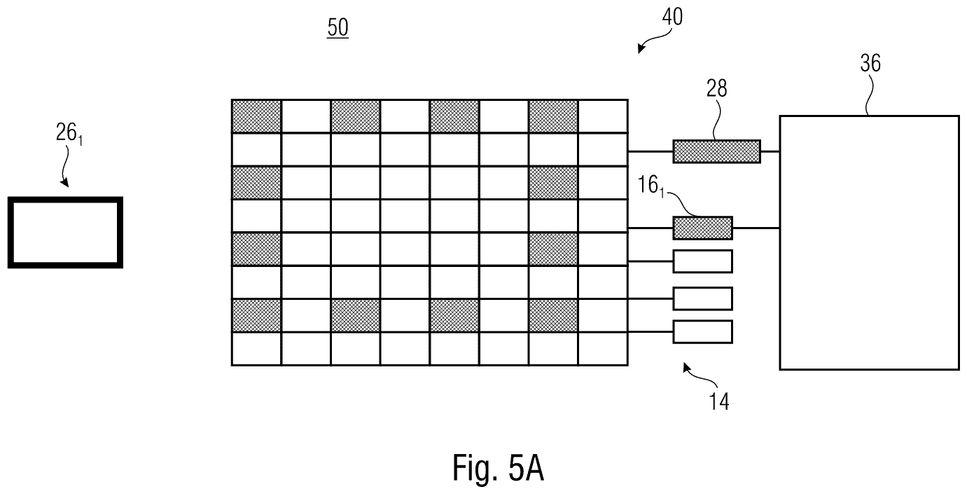

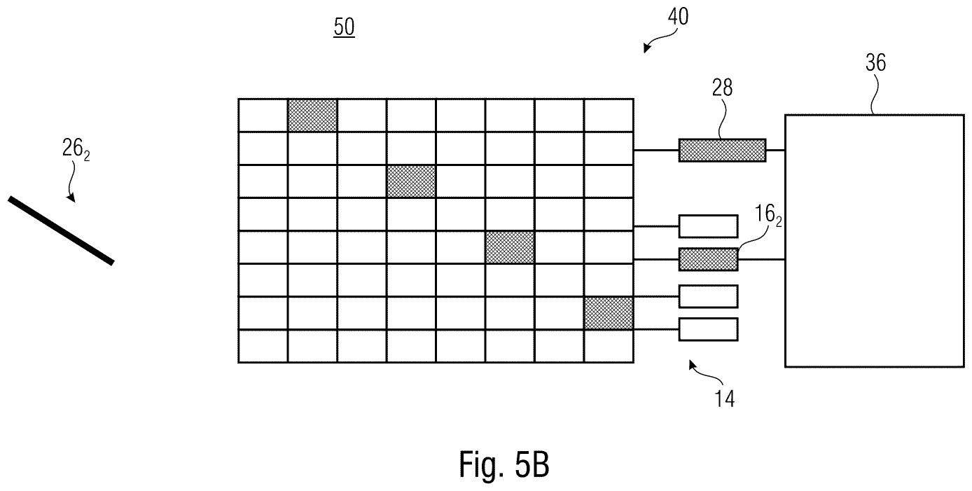

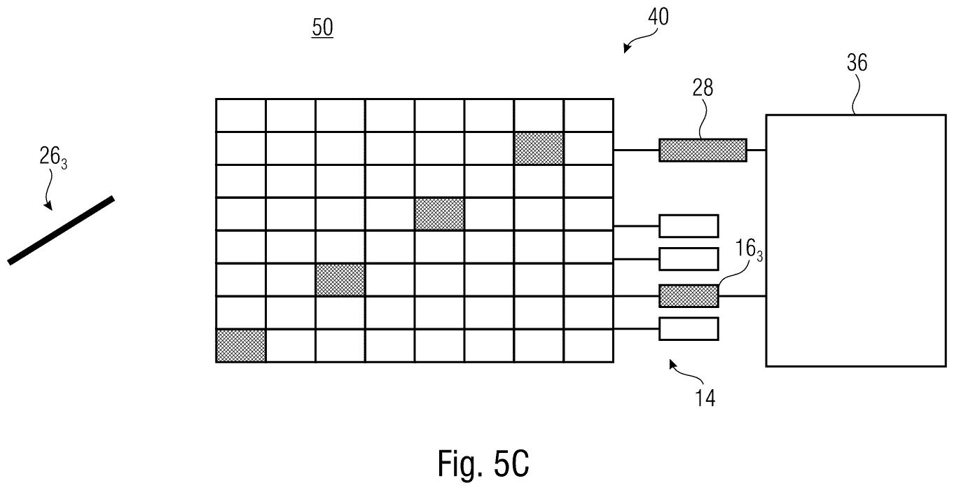

FIGS. 5a-d show schematic block diagrams of a display system 50 according to an embodiment. The display system 50 comprises a display device described herein, for example the display device 40, wherein the display device 10 or 20 may also be used easily. Furthermore, a control device 36 is provided, which is configured to select at least one of the subsets of the display elements as a selected subset for driving, like based on an operating state or information to be displayed, a user signal or the like. The control device is configured to drive the at least one selected subset together by means of the interconnection device 14. Thus, for example, for representing the pattern 26₁, the driving line 16₁ and the return line 28 can be contacted. For illustrating the pattern 26₂, the driving line 16₂ and the return line 28 can be contacted. For illustrating the pattern 263, the driving line 163 and the return line 28 can be contacted. For illustrating the pattern 264, the driving line 164 and the return line 28 can be driven. As described in connection with FIGS. 4a-d, the control device 36 can also drive several of the driving lines 16₁ to 16₄ simultaneously at a point in time, for example in order to represent an overlay of several patterns 26₁ to 26₄. This is of particular advantage when one or more of the patterns are projected in combination with the use of a color filter and/or a brightness attenuator, which can also be driven by the control device 36.

According to an embodiment, the control device 36 is configured to drive the selected subset by means of a common switching contact 16₁ to 16₄ of the interconnection device 14 unambiguously associated to the selected subset.

According to an embodiment, which can be implemented alternatively or additionally, the control device 36 is configured to control a brightness and/or a color of a pattern represented with the display device, for example by driving the optional color filters and/or brightness attenuators.

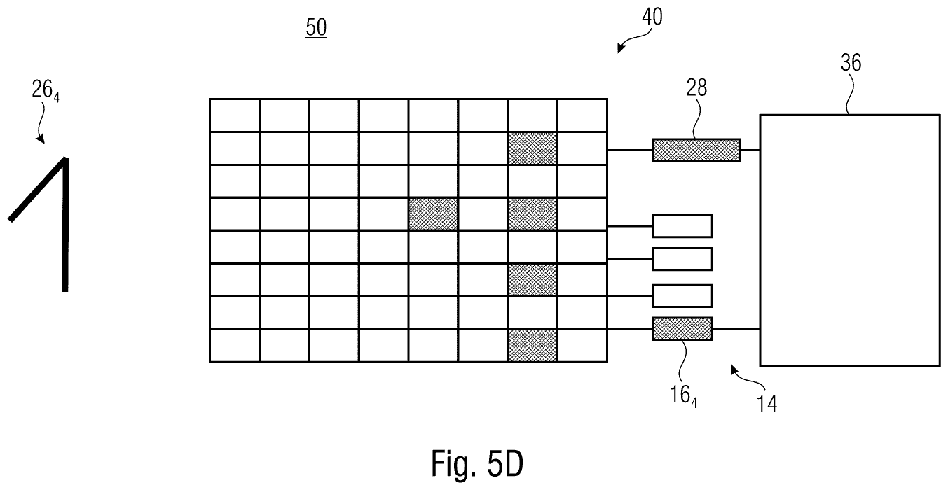

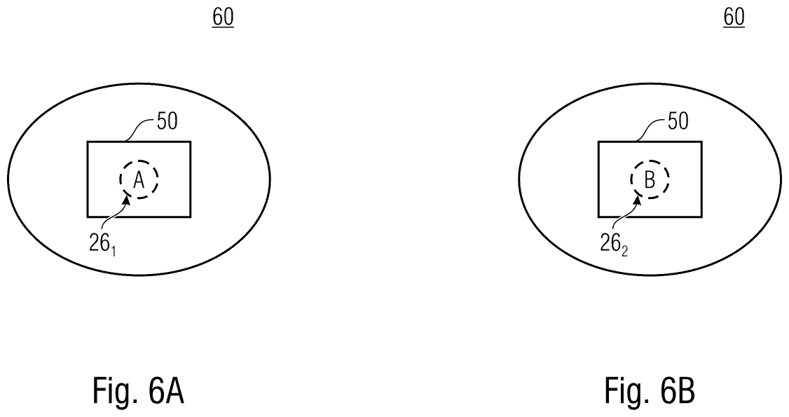

FIG. 6a shows a schematic block diagram of a multifunctional element 60 according to an embodiment. The multifunctional element 60 can be suitable for use in a system, for example an operating element, such as a button or a knob. Other multifunctional elements can comprise flaps, regulators, slides or the like, for example. The multifunctional element 60 comprises a display system described herein, for example the display system 50. The multifunctional element is configured to drive a subset of display elements associated to the operating state depending on an operating state of the system so that the display device represents a pattern associated to the operating state. For example, the multifunctional element can represent a first pattern 26₁, represented by “A”, in the operating state represented in FIG. 6a.

FIG. 6b shows a schematic block diagram of the multifunctional element 60 in another operating state of the system in which another pattern 26₂, represented by “B”, is illustrated by means of the display system 50.

In other words, the technology of the embodiments described herein is suitable for multifunctional buttons on devices, for example. If several functions are integrated in a button, between which it is possible to change back and forth by rotating or pressing the button, for example, the display technology presented here can be installed in the button and thus always display a corresponding symbol for the selected function.

A multifunctional element described herein can be used in different fields of application. For example, an operating element, for example a control button, can control a temperature, represented with a first pattern 26₁, in a first operating state of an air conditioning system and a volume flow, which can be displayed with another pattern 26₂, which is represented on or in the multifunctional element, in another operating state. A corresponding multifunctional element, in particular an actuation button, can be used in a space-saving manner to represent a plurality of pieces of information.

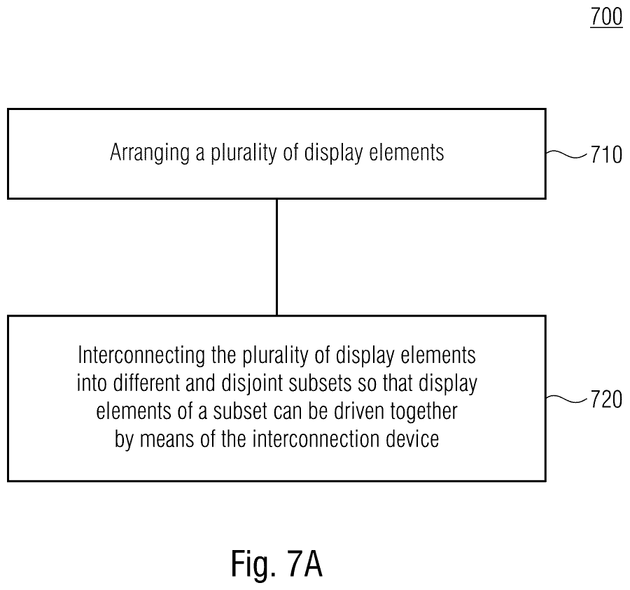

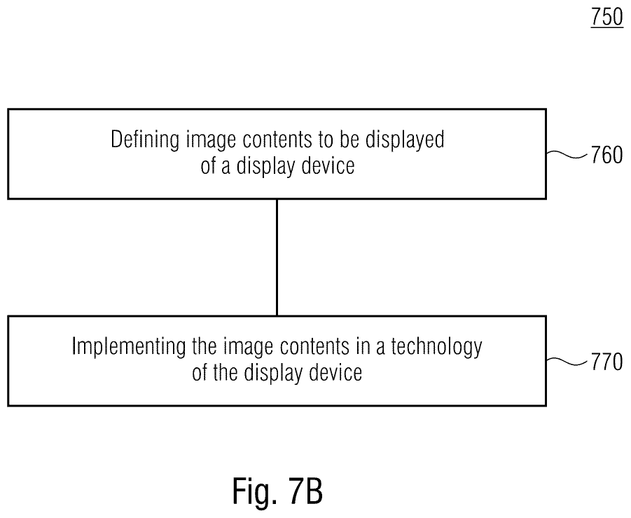

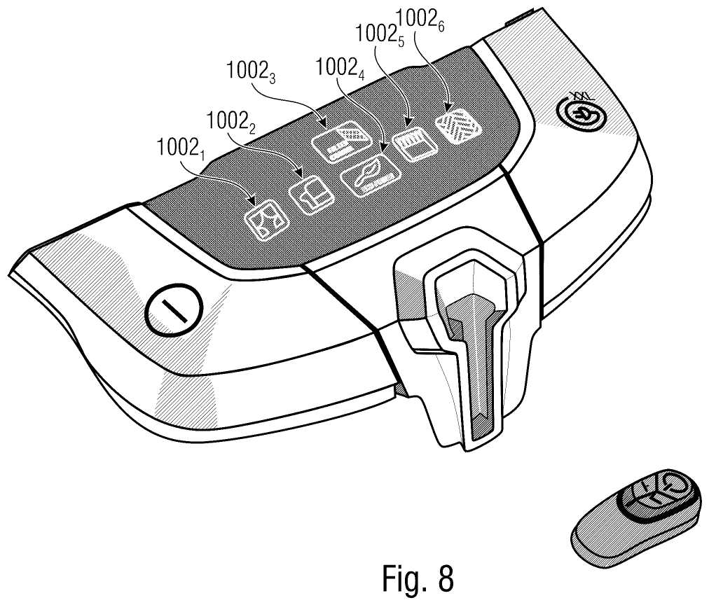

FIG. 7 shows a schematic flow chart of a method 700 according to an embodiment, which can be used for producing a display device described herein, for example. In step 710, a plurality of display elements are arranged. In step 720, the plurality of display elements are interconnected into different and disjoint subsets so that display elements of a subset can be driven together by means of the interconnection device. Preferably, during driving a subset, display elements of other subsets are kept inactive or are not driven, provided that the subsets to which these display elements are associated are not driven in a combinatorial manner, as described in connection with FIGS. 4a-5d. An order of steps 710 and 720 can be as desired and can also take place at least in parts at the same time. For example, in the case of omitting a μLED, like by not arranging the luminous element 24 in FIG. 1b-c or in the case of not opening the insulator 17 in FIG. 1b-c, the interconnection can be carried out, but the active luminous element can be omitted, wherein step 720 can be performed before step 710.

An embodiment of the present invention relates to a method 750, which comprises step 760, in which image contents of a display device to be represented are defined, like by creating a layout comprising the symbols to be represented. In step 770, the image contents are implemented in a technology of the display device, like μLED or OLED, i.e., producing the display device, wherein the image contents are thus fixed and possibly defined invariably. Such a method is represented in FIG. 7b.

According to an optional implementation of the method 700, a uniform color filter for display elements of a subset is arranged using a printing method or using a transfer technique.

For example, the arrangement of a uniform color filter can be performed such that different and respective uniform color filters are arranged on different subsets of display elements, like by means of printing methods or an identical or different transfer techniques.

According to an embodiment, the method 700 can be implemented with an optional step, in which a brightness attenuation element is arranged for at least one of the plurality of display elements.

Embodiments described herein solve the technical problem of providing a display technology with acceptable resolution and sufficient representation possibilities in limited installation space. Advanced display technologies entail complex driving electronics, which in turn use larger areas and volume in the final product. Moreover, due to the costs, these can only be used in high-price or high-quality products. In contrast, simple displays, for example, so-called 7-segment displays, are only suitable for very few ways of application due to the very limited representation possibilities. These disadvantages are eliminated by the embodiments described herein. Embodiments combine the simple integration possibility of the directly driven displays with the high-resolution capabilities of matrix-based displays. Due to the high resolution, it is above all possible to make individual symbols appear virtually at the same location, as described in connection with the use of subpixels. For this purpose, adjacent pixels are each associated to a different symbol according to a advantageously fixed, regular pattern. Driving always takes place via associated columns. The shape and design of the symbols to be represented are relatively free, wherein a broad spectrum of images can be realized. The individual images can be realized in the display with the aid of subpixels within the pixels, see the explanations relating to FIGS. 4a to 4b for this purpose.

In production technology or technology, the corresponding luminous areas, which are used to represent the images, are made available per pixel. The assignment of which subpixel is used or entailed for which image can be defined beforehand in a corresponding layout and thus each image can be fixed. The implementation or shape of the individual luminous areas of each subpixel can also be adapted individually so that an even more precise representation of the displayed image is made possible.

The number of subpixels per pixel results in the number of images, which can be represented by the corresponding display or pixel. If such a fixed association is desired or implemented, for example, a higher number of images can be represented in a pixel according to FIG. 3b than in the embodiment according to FIG. 3a.

These predefined and superimposed images can result in driving, which is greatly reduced in its complexity compared to known concepts. For each displayed image, only one contact is used, which drives the corresponding subpixels, and one contact, which connects the cathode of the LEDs, for example, like the return line 28. A correspondingly inverse driving is easily possible. With a 4×4 pixel matrix, which is described by way of example in connection with the display device 40, five supply lines on the display can thus already be sufficient, since the cathode or the cathode connection can be implemented identically for all subpixels or be connected to one another.

The brightness of individual luminous areas can be identical for each subpixel or can be varied by different technological possibilities. Similarly to the images, the brightness can already be set via the technology or production technology. This includes, similarly to the representation of the pixels, the shape and/or size of the luminous areas, which can be adapted individually. Such adjustability can also be used to define the brightness per subpixel or a defined programmable element, like a resistive element, which is connected in series with the supply line. In addition, a programmable resistive element can also be connected in series with the supply line, wherein the brightness can be defined during operation of the display. This resistive element can be of the EPROM (Erasable Programmable Read-Only Memory), EEPROM (Electrically Erasable Programmable Read-Only Memory), flash transistor or ferroelectric transistor type. Furthermore, such a resistive element can also be or comprise a phase change memory or another non-volatile physical, chemical, optical or other component. Such a resistive element can be configured to switch the display elements, i.e., for example, to change the operating state between “on” and “off” depending on the set resistance value. This includes brightness regulation up to a reduction up to an off state. Alternatively or additionally, the indicated technology can also be used in connection with brightness attenuating elements, which can be applied individually in the emission direction on the luminous area and wherein the brightness of each luminous area can also be defined.

With respect to the coloring of each illustrating image, it is possible for each luminous element, display element, of an associated driving line to be represented with a possibly uniform color image. This color filter can be realized on the one hand by a printing method, specifically inkjet printing, with corresponding devices with respect to controlling the ink propagation and drying behavior. In this case, each luminous element can be printed individually or a plurality of elements in a common process. On the other hand, a corresponding filter element can be placed on one, a plurality of or each luminous point by means of transfer technology, wherein this can also take place per subpixel or in a parallelized method.

A further particularity of display devices/displays proposed herein is the direct compatibility for producing more complex matrix displays. With the same dimensioning of the pixels, it may be sufficient to combine only groups of column lines to form common supply connections. Additional memory/driver elements and row lines can be dispensed with, and the manufacturing process is thus greatly simplified.

The display technology described herein may also be realized on different substrate surfaces. Thus, further properties can be integrated and/or other demands taken into account by means of a suitable choice, also with regard to the later application, such as, for example, transparency, for instance by means of glass substrates, stretchability, flexibility, for instance by means of polymer substrates.

A significant advantage of the technology is the low complexity of driving, which can still be below that of a 7-segment display. For each displayed image, only one supply line is used. A cathode used for the display operation can be used for all images. Already with a 7-segment display, each segment is driven with a supply line and generally several segments are used in order to generate a symbol. Moreover, while the representation possibilities are greatly limited with such displays, almost any symbol can be generated with high resolution by the implementation of a display device described herein. This in turn offers the advantage that no passive matrix display or active matrix display has to be used, which would far exceed the embodiments described herein in terms of its complexity and the production costs.

As a result of the low complexity of the driving and the high resolution possible at the same time, the further advantage results that the display can be integrated in applications with very limited installation space. Moreover, transparent applications or the integration on curved surfaces can also be implemented by using a corresponding substrate material.

Embodiments are suitable for using a display technology especially for limited installation space and can serve for further space saving or also upgrading of electronic equipment elements. Several displays, which are placed next to one another, can be implemented in a display element with the aid of the display, for instance indicator lamps, in particular in the automotive sector. According to the application examples, buttons and control units can be upgraded and the symbols corresponding to their functions can be displayed. Moreover, the technology is suitable for any application field, in which a technologically complex display is not worthwhile due to the costs caused.

Although some aspects have been described in connection with a device, it is understood that these aspects also represent a description of the corresponding method so that a block or a component of a device is also to be understood as a corresponding method step or as a feature of a method step. In analogy, aspects described in connection with or as a method step also represent a description of a corresponding block or detail or feature of a corresponding device.

While this invention has been described in terms of several embodiments, there are alterations, permutations, and equivalents which fall within the scope of this invention. It should also be noted that there are many alternative ways of implementing the methods and compositions of the present invention. It is therefore intended that the following appended claims be interpreted as including all such alterations, permutations and equivalents as fall within the true spirit and scope of the present invention.

### REFERENCES

[1]

Direct Drive, Multiplex, and Passive Matrix, Karlheinz Blankenbach, Andreas Hudak and Michael Jentsch, Handbook of Visual Display Technology, DOI 10.1007/978-3-319-14346-0_33
[2] Active Matrix Driving, Karlheinz Blankenbach in Handbook of Visual Display Technology, DOI 10.1007/978-3-319-14346-0_34
[3] Internet Source:

https://www.marquardt.com/solutions/bedienelemente-hmi/touchbedieneinheiten

1. A display device comprising:
a plurality of display elements;
an interconnection device configured to interconnect different and disjoint subsets of the display elements with one another;
wherein display elements of a subset can be driven together by means of the interconnection device.

2. The display device according to claim 1, wherein the interconnection device is configured to interconnect the subsets with one another invariably.

3. The display device according to claim 2, wherein the interconnection device is configured to interconnect the subsets by means of a fixed wiring.

4. The display device according to claim 1, wherein the plurality of display elements is arranged in a regular array with a plurality of columns and a plurality of rows.

5. The display device according to claim 1, wherein each of the subsets is unambiguously associated to a predefined pattern to be represented by the display device; wherein the display device is configured to represent the predefined pattern associated to the subset by means of the common driving of the display elements.

6. The display device according to claim 1, wherein each of the subsets of display elements can be driven unambiguously via a driving line of the interconnection device unambiguously associated to the subgroup.

7. The display device according to claim 1, wherein a first color filter is arranged with respect to display elements of a first subset of display elements; and a second color filter is arranged with respect to display elements of a second subset of display elements.

8. The display device according to claim 1, comprising at least one color filter arranged, with respect to at least one display element, opposite to a viewing direction, and configured to filter light provided by the display element.

9. The display device according to claim 1, wherein the display elements of a subset comprise a common contacting, and when the common contacting is wired, either none of the display elements of the subset is activated or all of the display elements of the subset are activated.

10. The display device according to claim 9, wherein each display element comprises a first electrical connection and a second electrical connection, wherein first connections of different display elements of a subset of the display elements are interconnected with one another by means of the interconnection device and electrically separated from first connections of display elements of other subsets;
wherein second connections of display elements of different subsets are interconnected with one another by means of the interconnection device.

11. The display device according to claim 1, wherein the plurality of display elements is a first plurality of subpixels,
wherein the plurality of subpixels is grouped into a second plurality of pixels;
wherein each subset of display elements comprises at most one subpixel of a pixel.

12. The display device according to claim 11, wherein different subpixels of a pixel are driven when driving different subsets of the display elements.

13. The display device according to claim 11, wherein each pixel of the second plurality of pixels comprises a matching number of subpixels.

14. The display device according to claim 1, wherein the plurality of display elements comprise a display surface geometry and/or surface area which is matching with respect to a surface area, or an individual display surface geometry and/or surface area.

15. The display device according to claim 1, wherein the plurality of display elements ist configured for providing a matching display brightness, a display brightness matching in groups or an individual display brightness.

16. The display device according to claim 1, comprising a resistive element, which is connected as part of or in series with a supply line of at least one of the subsets of display elements, and is configured to set a brightness of the display elements or to switch the display elements.

17. The display device according to claim 16, wherein the resistive element is a controllable element, in particular a programmable resistive element.

18. The display device according to claim 1, comprising at least one brightness attenuation element arranged, with respect to at least one of the display elements, opposite to a viewing direction, and configured to attenuate a brightness provided by the display element opposite to the viewing direction.

19. The display device according to claim 18, wherein the brightness attenuation element is controllable with respect to a degree of attenuation with which the brightness of the display element is attenuated.

20. The display device according to claim 1, comprising a plurality of sensor elements, wherein each sensor element of the plurality of sensor elements is associated exactly to a subset of display elements; or is interconnected into one of at least one group of sensor elements.

21. The display device according to claim 1, comprising at least one subregion of an arrangement of the display elements, which is associated with a display element in the arrangement and is formed to be incapable of functioning with respect to a display function.

22. A display system comprising:
a display device according to claim 1; and
a control device configured to select at least one of the subsets of the display elements as a selected subset for driving and to drive the at least one selected subset together by means of the interconnection device.

23. The display system according to claim 22, wherein the control device is configured to drive the selected subset by means of a common switching contact of the interconnection device unambiguously associated to the selected subset.

24. The display system according to claim 22, wherein the control device is configured to control a brightness and/or a color of a pattern represented with the display device.

25. A multifunctional element for a system, wherein the multifunctional element comprises:
a display system according to claim 22,
wherein the multifunctional element is configured to drive a subset of display elements associated to the operating state depending on an operating state of the system so that the display device represents a pattern associated to the operating state.

26. The multifunctional element according to claim 25, which is an actuation button.
